(19) United States
(12) Patent Application Publication
(10) Pub. No.: US 2024/0387207 A1
(43) Pub. Date: Nov. 21, 2024

(54) SUBSTRATE PROCESSING APPARATUS AND SUBSTRATE PROCESSING METHOD

(71) Applicant: SEMES CO., LTD., Cheonan-si (KR)

(72) Inventors: Ki Won HAN, Ansung-si (KR); Hee Chan KIM, Hwasung-si (KR)

(73) Assignee: SEMES CO., LTD., Cheonan-si (KR)

(21) Appl. No.: 18/630,230

(22) Filed: Apr. 9, 2024

(30) Foreign Application Priority Data
May 19, 2023 (KR) 10-2023-0065047

(51) Int. Cl. H01L 21/67; H01L 21/677; H01L 21/687

(52) U.S. Cl. CPC H01L 21/6715; H01L 21/67196; H01L 21/67248; H01L 21/67742; H01L 21/68764

(57) ABSTRACT

Disclosed is a substrate processing apparatus and a substrate processing method that may increase the amount of substrates produced by preventing a main transfer robot that transfers a substrate between a liquid treatment chamber and a heat treatment chamber from transferring an edge-exposed substrate. The substrate processing apparatus may include: an index module; a buffer module; a treatment module; and an interface module, in which the index module includes: a load port in which a container receiving a substrate is placed; and an index frame provided with an index robot for transferring the substrate between the container placed in the load port and the buffer module, the buffer module is provided with a buffer in which the substrate is placed, the treatment module includes: a liquid treatment chamber for liquid treating the substrate loaded from the buffer module; a heat treatment chamber for heat treating the substrate received from the buffer module; and a transfer chamber disposed between the liquid treatment chamber and the heat treatment chamber, and provided with a main transfer robot for transferring substrates to the buffer module, the liquid treatment chamber, and the heat treatment chamber, respectively, the interface module includes: an interface frame positioned between the treatment module and an external exposure device; an edge exposure chamber disposed within the interface frame and performing edge exposure processing on the substrate; and an interface robot disposed within the interface frame and transferring the substrate, and each of the main transfer robot and the interface robot loads or unloads the substrate into or from the edge exposure chamber.

### CROSS-REFERENCE TO RELATED APPLICATIONS

This application claims priority to and the benefit of Korean Patent Application No. 10-2023-0065047 filed in the Korean Intellectual Property Office on May 19, 2023, the entire contents of which are incorporated herein by reference.

### TECHNICAL FIELD

The present invention relates to a substrate processing apparatus and a substrate processing method, and particularly, to a substrate processing apparatus and a substrate processing method for processing a substrate.

### BACKGROUND ART

In the semiconductor manufacturing process, the exposure process applies photoresist to a substrate, exposes the photoresist by using a mask, and develops the exposed substrate to form a circuit pattern on the photoresist film on the substrate.

In this case, the typical semiconductor manufacturing process also performs an edge exposure process to reduce particles by exposing the edges of the photoresist before exposing the photoresist film into a circuit pattern.

In this process, the edge exposure process is carried out by a main transfer robot that loads the substrate into the edge exposure chamber to expose the edge of the substrate, and then transfers the edge-exposed substrate back to the buffer side for temporary loading. The substrate temporarily loaded in the buffer is then loaded to the exposure device by another transfer robot.

In this case, the main transfer robot not only serves to transfer the edge-exposed substrate, but also for serves to transfer the substrate to each of the liquid treatment chambers and the heat treatment chambers.

As a result, the main transfer robot repeatedly performs the task of loading the substrate to the edge exposure chamber and then transferring the edge-exposed substrate back to the buffer side, which increases the time to transfer the edge-exposed substrate, resulting in lower substrate productivity.

### SUMMARY OF THE INVENTION

The present invention has been made in an effort to provide a substrate processing apparatus and a substrate processing method that may increase the amount of substrates produced by preventing a main transfer robot that transfers a substrate between a liquid treatment chamber and a heat treatment chamber from transferring an edge-exposed substrate.

The object of the present invention is not limited thereto, and other objects not mentioned will be clearly understood by those of ordinary skill in the art from the following description.

An exemplary embodiment of the present invention provides a substrate processing apparatus including: an index module; a buffer module; a treatment module; and an interface module, in which the index module includes: a load port in which a container receiving a substrate is placed; and an index frame provided with an index robot for transferring the substrate between the container placed in the load port and the buffer module, the buffer module is provided with a buffer in which the substrate is placed, the treatment module includes: a liquid treatment chamber for liquid treating the substrate loaded from the buffer module; a heat treatment chamber for heat treating the substrate received from the buffer module; and a transfer chamber disposed between the liquid treatment chamber and the heat treatment chamber, and provided with a main transfer robot for transferring substrates to the buffer module, the liquid treatment chamber, and the heat treatment chamber, respectively, the interface module includes: an interface frame positioned between the treatment module and an external exposure device; an edge exposure chamber disposed within the interface frame and performing edge exposure processing on the substrate; and an interface robot disposed within the interface frame and transferring the substrate, and each of the main transfer robot and the interface robot loads or unloads the substrate into or from the edge exposure chamber.

According to the exemplary embodiment, the main transfer robot may be provided to load the substrate into the edge exposure chamber, and the interface robot may be provided to unload the substrate loaded into the edge exposure chamber.

According to the exemplary embodiment, the main transfer robot may be provided not to unload the substrate within the edge exposure chamber.

According to the exemplary embodiment, the treatment module may further include: an application module for performing an application process on the substrate; and a development module for performing a developing process on the substrate, the application module and the development module may each include the liquid treatment chamber, the heat treatment chamber, and the main transfer robot, the application module and the development module may be provided to be stacked, and the main transfer robot provided in the application module may be provided to transfer the substrate to the edge exposure chamber.

According to the exemplary embodiment, the edge exposure chamber may include: an edge exposure housing having a treatment space; an edge exposure support unit disposed within the treatment space of the edge exposure housing and supporting the substrate; and an exposure source disposed within the treatment space of the edge exposure housing and irradiating an edge of the substrate with light, and the edge exposure housing may further include an inlet provided as a passageway for the main transfer robot to be moved into the treatment space, and an outlet provided as a passageway for the interface robot to be moved into the treatment space.

According to the exemplary embodiment, a wall body in which the inlet is formed and a wall body in which the outlet is formed may be disposed perpendicularly to each other.

According to the exemplary embodiment, the interface module may further include an interface buffer for loading the substrate unloaded from the edge exposure chamber by the interface robot, and in this case, the interface buffer may be disposed in an upper space or a lower space of the edge exposure chamber.

According to the exemplary embodiment, the outlet of the edge exposure chamber and an entrance port of the interface buffer may have the same direction in which the substrate enters and exits.

According to the exemplary embodiment, the interface buffer may include: an interface first buffer provided for loading a substrate unloaded from the edge exposure chamber; and an interface second buffer provided for loading, by the interface robot, the substrate exposed by an exposure device.

According to the exemplary embodiment, the interface robot may further include: a first interface robot for unloading the substrate edge-exposed in the edge exposure chamber and loading the substrate into the interface first buffer, and for transferring the substrate loaded in the interface first buffer to the exposure device; and a second interface robot disposed opposite the first interface robot with the edge exposure chamber interposed therebetween, and provided for loading substrate exposed by the exposure device to the interface second buffer.

According to the exemplary embodiment, the second interface robot may be provided in a position opposite to a direction in which the outlet of the edge exposure housing is formed.

According to the exemplary embodiment, the interface module may further include a defect inspection unit which is installed in a path for loading the substrate from the transfer chamber to a side of the edge exposure chamber, and inspects a defect of the substrate loaded into the edge exposure chamber.

According to the exemplary embodiment, the main transfer robot may be provided to be movable along a longitudinal direction of the transfer chamber, one end in the longitudinal direction of the transfer chamber may be adjacent to the buffer module, the other end in the longitudinal direction of the transfer chamber may be adjacent to the interface module, and the edge exposure chamber may be positioned adjacent the other end of the transfer chamber.

Another exemplary embodiment of the present invention provides a substrate processing method including: a film treatment operation in which a main transfer robot transfers a substrate to each of a liquid treatment chamber and a heat treatment unit to form a liquid treatment film on the substrate, and heat treats the substrate on which the liquid treatment film is formed; an edge exposure operation in which the main transfer robot loads the substrate on which the film treatment operation has been performed to an edge exposure chamber of an interface module formed at a front end of an exposure device to edge expose the substrate; and a circuit pattern exposure operation in which an interface robot loads the substrate edge-exposed in the edge exposure operation into the exposure device to expose a circuit pattern.

According to the exemplary embodiment, the method may further include a post-edge-exposure substrate loading operation which is performed between the edge exposure operation and the circuit pattern exposure operation, and in which the interface robot loads the edge-exposed substrate in the edge-exposure chamber into an interface buffer, in which the circuit pattern exposure operation may include loading, by the interface robot, the edge-exposed substrate in the interface buffer to the exposure device.

According to the exemplary embodiment, in the edge exposure operation, the main transfer robot may not unload the substrate from the edge exposure chamber after loading the substrate into the edge exposure chamber.

According to the exemplary embodiment, in the post-edge-exposure substrate loading operation, the main transfer robot may be engaged in transferring the substrate between the liquid treatment chamber and the heat treatment chamber while the interface robot loads and unloads the edge-exposed substrate.

According to the exemplary embodiment, the main transfer robot may be provided to be movable within the transfer chamber along a longitudinal direction of the transfer chamber, and the edge exposure operation may include loading, by the main transfer robot, the substrate into the edge exposure chamber on a line extending along the longitudinal direction of the transfer chamber.

According to the exemplary embodiment, the edge exposure operation may include, when the substrate is loaded into the edge exposure chamber, inspecting, by a defect inspection unit, a defect of the substrate.

Still another exemplary embodiment of the present invention provides a substrate processing apparatus including an application module that performs an application process on a substrate, and a development module that performs a development process on a substrate, in which the application module and the development module each include the liquid treatment chamber, the heat treatment chamber, and the main transfer robot, the application module and the development module are provided to be stacked, and the main transfer robot provided in the application module is provided to transfer the substrate to the edge exposure chamber, the main transfer robot is provided to be movable along a longitudinal direction of the transfer chamber, one end in the longitudinal direction of the transfer chamber is adjacent to the buffer module, the other end in the longitudinal direction of the transfer chamber is adjacent to the interface module, and the edge exposure chamber is positioned adjacent the other end of the transfer chamber, the edge exposure chamber includes: an edge exposure housing having a treatment space; an edge exposure support unit disposed within the treatment space of the edge exposure housing and supporting the substrate; and an exposure source disposed within the treatment space of the edge exposure housing and irradiating an edge of the substrate with light, and the edge exposure housing further includes an inlet provided as a passageway for the main transfer robot to be moved into the treatment space, and an outlet provided as a passageway for the interface robot to be moved into the treatment space, a wall body in which the inlet is formed and a wall body in which the outlet is formed are disposed perpendicularly to each other, and the outlet of the edge exposure chamber and an entrance port of the interface buffer have the same direction in which the substrate enters and exits, and the interface module further includes an interface buffer for loading the substrate unloaded from the edge exposure chamber by the interface robot, and the interface buffer is disposed in an upper space or a lower space of the edge exposure chamber, and includes: an interface first buffer provided for loading a substrate unloaded from the edge exposure chamber; and an interface second buffer provided for loading, by the interface robot, the substrate that has been exposed by an exposure device, the interface robot includes: a first interface robot for unloading the substrate edge-exposed in the edge exposure chamber and loading the substrate into the interface first buffer, and for transferring the substrate loaded into the interface first buffer to the exposure device; and a second interface robot disposed opposite the first interface robot with the edge exposure chamber interposed therebetween, and provided for loading substrate exposed by the exposure device to the interface second buffer, and the second interface robot is provided in a position opposite to a direction in which the outlet of the edge exposure housing is formed, and the interface module further includes a defect inspection unit that is installed around the inlet of the edge exposure chamber, and inspects a defect of the substrate loaded into the edge exposure chamber.

According to the present invention, the main transfer robot that transfers the substrate between the liquid treatment chamber and the heat treatment chamber does not transfer the edge-exposed substrate, thereby increasing the production volume of the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a perspective view schematically illustrating a substrate processing apparatus of the present invention.

FIG. 2 is a cross-sectional view viewed in the direction of the arrow through A-A illustrated in FIG. 1.

FIG. 3 is a cross-sectional view viewed in the direction of the arrow through B-B illustrated in FIG. 1.

FIG. 4 is a cross-sectional view viewed in the direction of the arrow through C-C illustrated in FIG. 1.

FIG. 5 is a cross-sectional view viewed in the direction of the arrow through D-D illustrated in FIG. 1.

FIG. 6 is a cross-sectional view viewed in the direction of the arrow through E-E illustrated in FIG. 1.

FIG. 7 is a perspective view illustrating one example of a cooling chamber of FIG. 3.

FIG. 8 is a top plan view illustrating one example of a main transfer robot of FIGS. 3 and 4.

FIG. 9 is a longitudinal sectional view schematically illustrating one example of a liquid treatment chamber of FIG. 3.

FIG. 10 is a top plan view schematically illustrating a heat treatment chamber of FIGS. 3 and 4.

FIG. 11 is a longitudinal sectional view of the heat treatment chamber of FIG. 10.

FIG. 12 is a flowchart of a substrate processing method before exposure according to an exemplary embodiment of the present invention.

FIG. 13 is a diagram schematically illustrating a substrate transfer path according to the sequence of the substrate processing method of FIG. 12.

FIG. 14 is a flowchart of the substrate processing method after exposure according to the exemplary embodiment of the present invention.

FIG. 15 is a diagram schematically illustrating a substrate transfer path according to the sequence of the substrate processing method of FIG. 14.

### DETAILED DESCRIPTION

Hereinafter, exemplary embodiments for carrying out the present invention will be described with reference to the accompanying drawings, and in this case, when it is the that a certain constituent element “includes” a certain constituent element throughout the specification, it is considered to mean that it may further include other constituent elements rather than controlling other constituent elements unless otherwise stated. In addition, terms such as “ . . . unit” described in the specification is considered to mean a unit that processes at least one function or operation when describing electronic hardware or electronic software, and mean one component, a function, a use, a point, or a driving element when describing a mechanical device. In addition, hereinafter, the same or similar configurations will be described by using the same reference numerals, and overlapping descriptions of the same constituent elements will be omitted.

Further, when an element or layer is referred to in the present invention as being “on,” “connected to,” “coupled to,” “attached to,” “adjacent to,” or “covering” another element or layer, it may be directly on, connected to, coupled to, attached to, adjacent to, or covering said other element or layer, or intermediate elements or layers may exist. Conversely, when an element is referred to as being “directly on,” “directly connected to,” or “directly bonded to” another element or layer, it is to be understood that no intervening elements or layers are present. Throughout the specification, the same reference numeral refers to the same element. As used in the present invention, the term “and/or” includes all combinations and sub-combinations of one or more of the enumerated items.

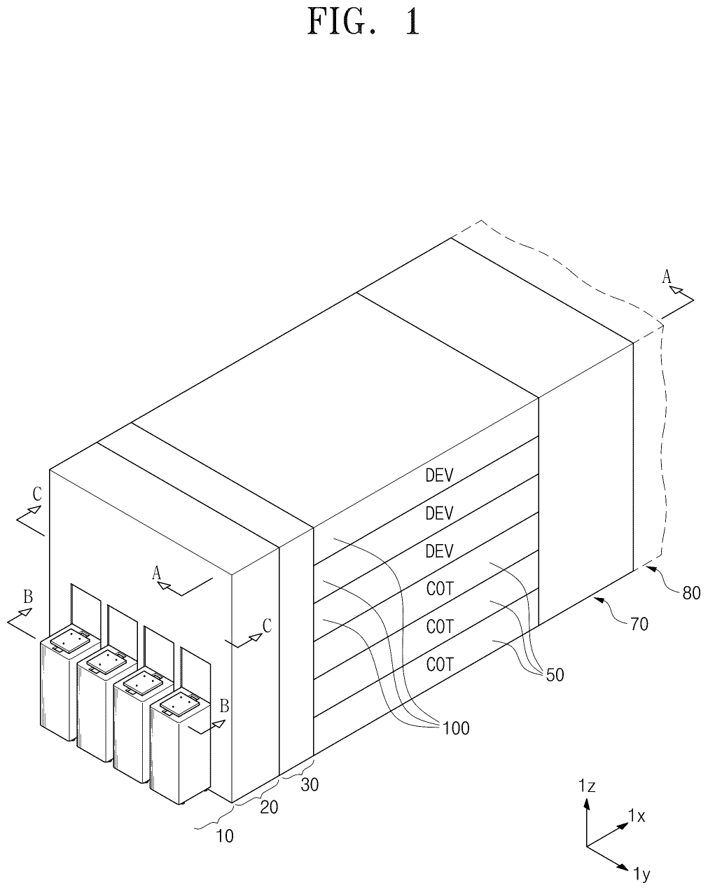

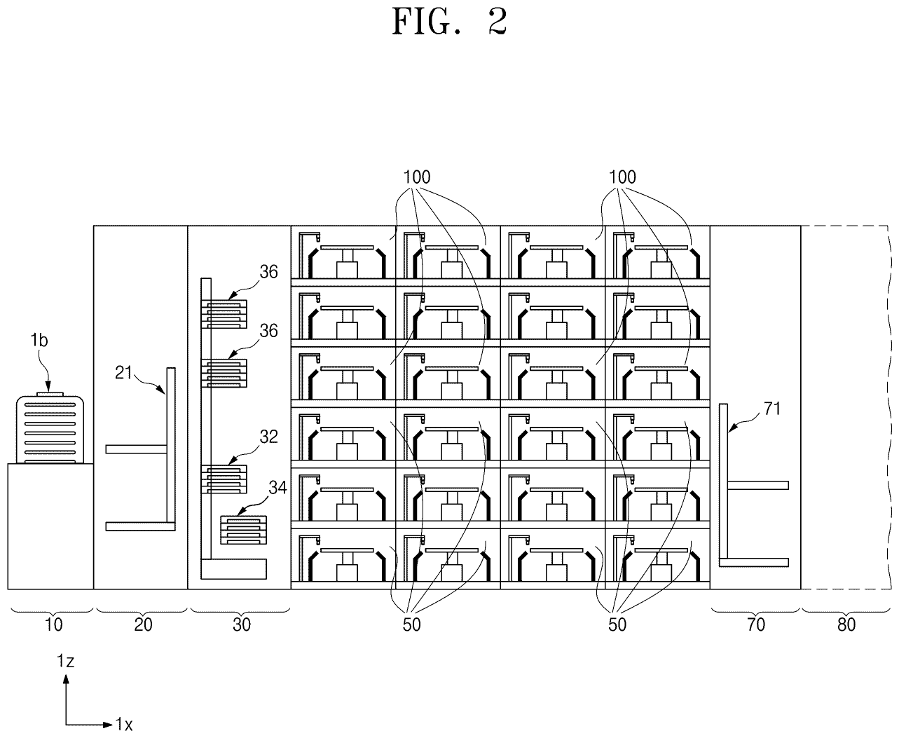

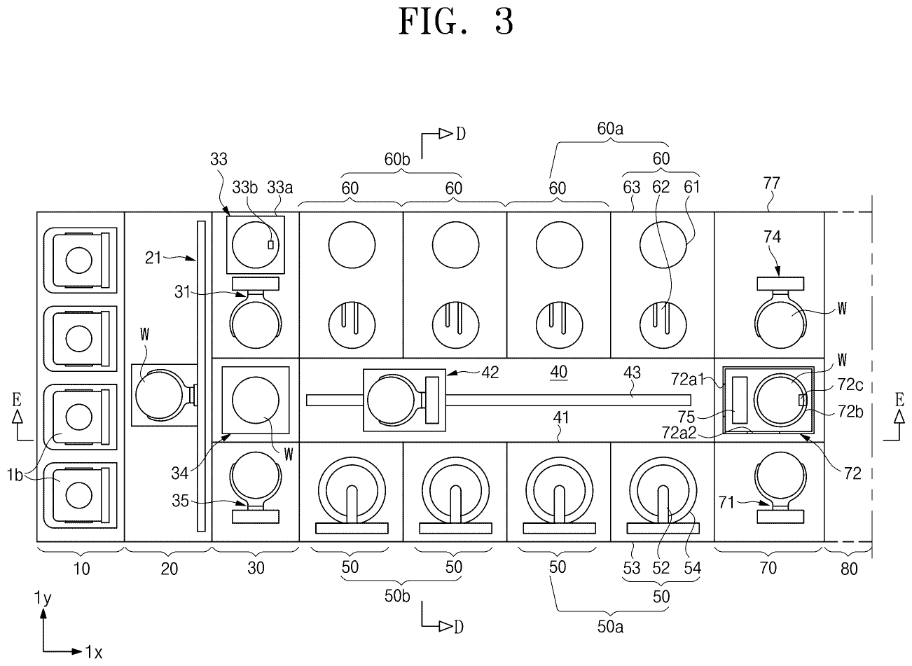

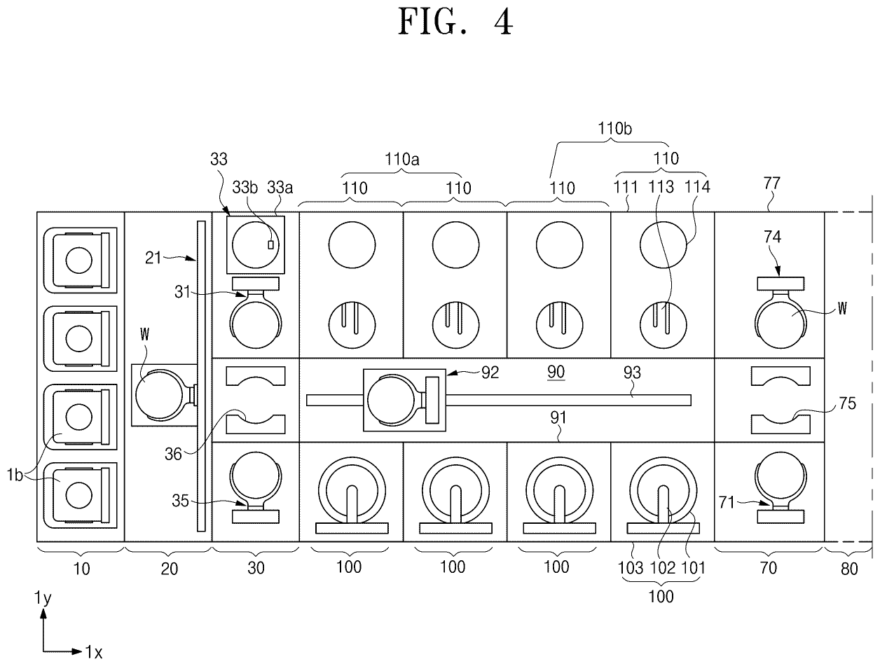

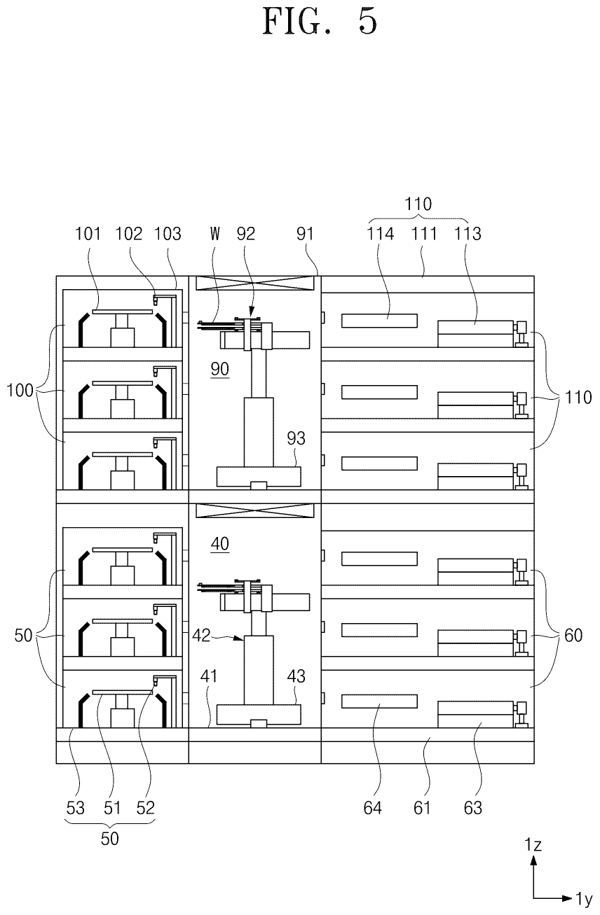

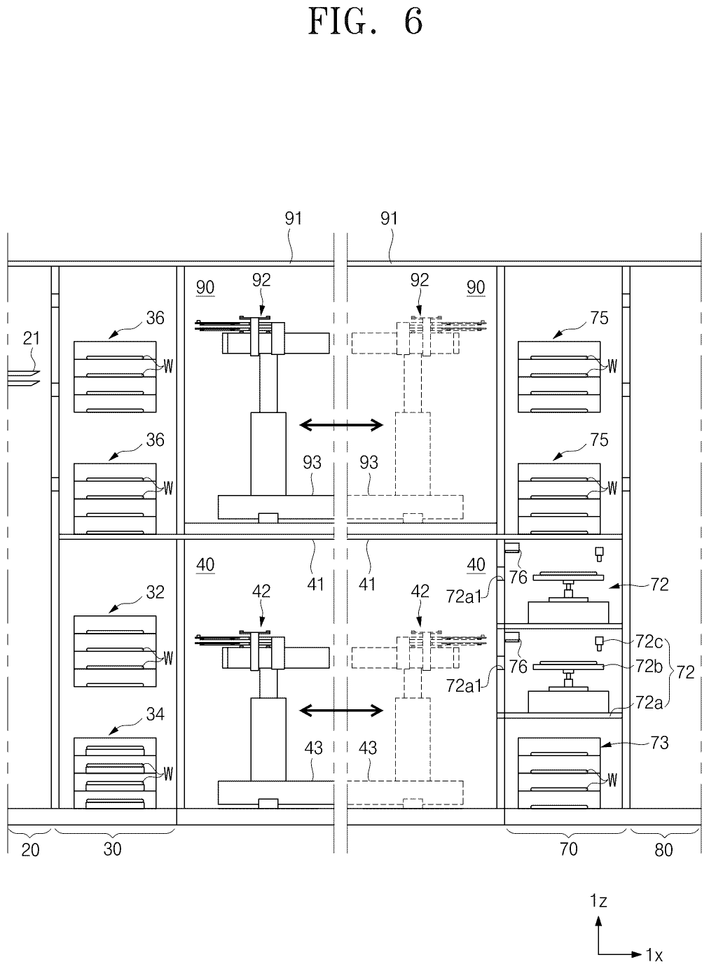

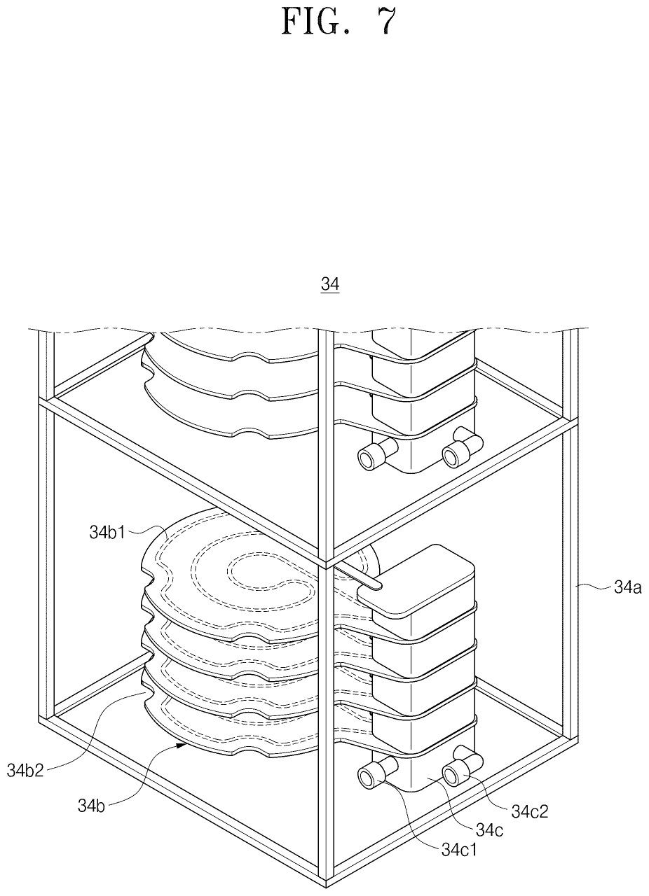

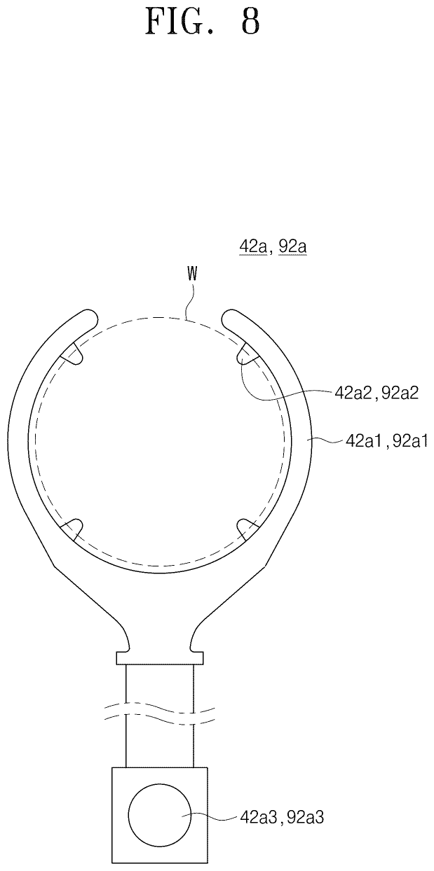

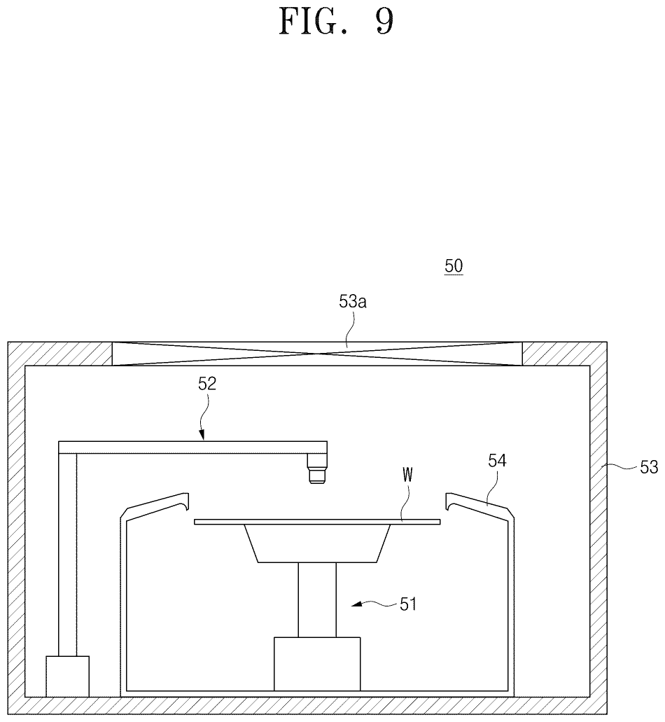

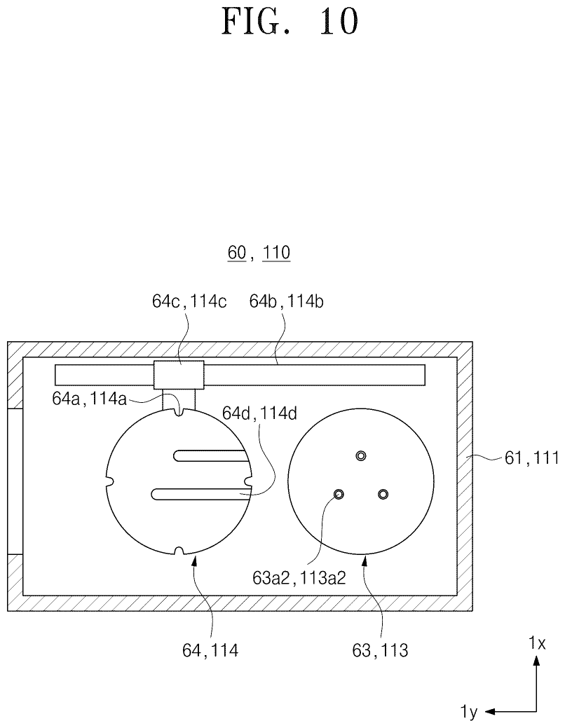

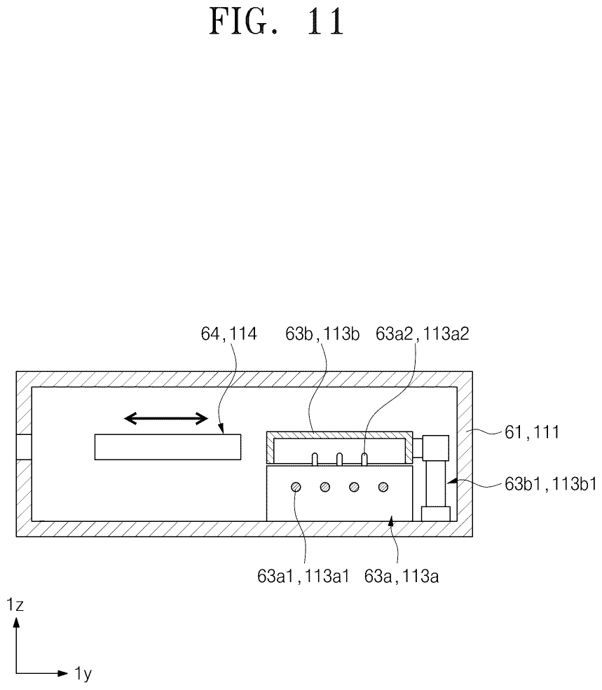

FIG. 1 is a perspective view schematically illustrating a substrate processing apparatus of the present invention. FIG. 2 is a cross-sectional view viewed in the direction of the arrow through A-A illustrated in FIG. 1. FIG. 3 is a cross-sectional view viewed in the direction of the arrow through B-B illustrated in FIG. 1. FIG. 4 is a cross-sectional view viewed in the direction of the arrow through C-C illustrated in FIG. 1. FIG. 5 is a cross-sectional view viewed in the direction of the arrow through D-D illustrated in FIG. 1. FIG. 6 is a cross-sectional view viewed in the direction of the arrow through E-E illustrated in FIG. 1. FIG. 7 is a perspective view illustrating one example of a cooling chamber of FIG. 3. FIG. 8 is a top plan view illustrating one example of a main transfer robot of FIGS. 3 and 4. FIG. 9 is a longitudinal sectional view schematically illustrating one example of a liquid treatment chamber of FIG. 3. FIG. 10 is a top plan view schematically illustrating a heat treatment chamber of FIGS. 3 and 4. FIG. 11 is a longitudinal sectional view of the heat treatment chamber of FIG. 10.

As illustrated in FIGS. 1 to 11, a substrate processing apparatus may include a load port 10, an index module 20, a buffer module 30, a first transfer chamber 40, a liquid treatment chamber 50, a first heat treatment chamber 60, an interface module 70, and an exposure device 80, and may further include a second transfer chamber 90, a development chamber 100, and a second heat treatment chamber 110.

Here, the direction in which the load port 10 faces the exposure device 80 is referred to as a first direction 1X, the direction perpendicular to the first direction 1X when viewed from above is referred to as a second direction 1Y, and the direction perpendicular to each of the first direction 1X and the second direction 1Y is referred to as a third direction 1Z.

The load port 10 receives containers 1b in which the substrates W are accommodated. The container 1b may hold a plurality of substrates W, in which case the container 1b may be transported by an autonomous transportation device, the OHT, and seated into the load port 10.

The index module 20 includes an index robot 21 mounted inside a frame. In this case, the index robot 21 is configured as a multi-degree-of-freedom robot, such that the hand loads the substrates W in the containers 1b into the frame, and unloads the substrates W loaded into the frame to the first buffer 32. Accordingly, the index robot 21 may be formed such that the hand directly handling the substrate W is movable in the axial direction of each of the first direction 1X, the second direction 1Y, and the third direction 1Z, and rotatable in the axial direction of each of the first direction 1X, the second direction 1Y, and the third direction 1Z. Furthermore, the index robot 21 of the index module 20 may unload the substrates W loaded in the first buffer 32 into the container 1b when the process processing is complete. However, in the present invention, the function of the index module 20 is not limited to the above example, and it is of course possible that the index module 20 may be implemented in any variation that allows for the loading and unloading of substrates W between the containers 1b and the buffer modules 30.

The buffer module 30 receives a plurality of substrates W mounted within the index module 20 from the hand of the index robot 21 and temporarily loads and stores the plurality of substrates W. The buffer module 30 also temporarily loads and stores the substrates W that have been processed for liquid treatment, development, and exposure. Furthermore, the buffer module 30 may perform a process of converting the hydrophilic substrate W to the hydrophobic substrate W and increasing the adhesive force of a photoresist film. Additionally, the buffer module 30 may progress a cooling process to easily remove particles formed on the substrate W.

As one example of the buffer module 30, the buffer module 30 may include a first buffer robot 31, a first buffer 32, a hydrophobization chamber 33, a cooling chamber 34, a second buffer robot 35, and a second buffer 36.

The first buffer robot 31 may load the substrates W mounted in the first buffer 32 by the index module 20 into the hydrophobization chamber 33. Furthermore, the first buffer robot 31 loads the substrate W after hydrophobic treatment from the hydrophobization chamber 33 to the cooling chamber 34. Accordingly, the first buffer robot 31 may be formed such that the hand directly handling the substrate W is movable in the axial direction of each of the first direction 1X, the second direction 1Y, and the third direction 1Z, and rotatable in the axial direction of the third direction 1Z.

The first buffer 32 may temporarily load the substrate W loaded by the index robot 21. Here, the substrates W temporarily loaded in the first buffer 32 are transferred to the hydrophobization chamber 33 by the first buffer robot 31, and the hydrophobized substrates W may be temporarily loaded on the first buffer 32. In this case, the first buffer 32 may be formed in the form in which a plurality of loading plates is arranged while being vertically spaced apart from each other to mount a plurality of substrates W. Further, the first buffer 32 may be formed with an increased number of loading plates as illustrated, or may include a plurality of stacked units, to increase the loading capacity. The first buffer 32 may be disposed in the upper portion of the cooling chamber 34, and the first buffer 32 may also be disposed in the lower portion of the cooling chamber 34 as needed.

The hydrophobization chamber 33 is a device that converts the hydrophilic substrate W loaded from the first buffer 32 by the first buffer robot 31 into a hydrophobic substrate W by treating the substrate W with the hydrophobic vapor. Such the hydrophobization chamber 33 may include a hydrophobic conversion housing 33a that houses the substrate W, and a hydrophobic vapor emission unit 33b that heats the hydrophobic material within the hydrophobic conversion housing 33a and supplies the hydrophobic material in the form of a vapor. In this case, as hydrophobic materials, hecamethyldisilazane (HMDS) vapor gas may be used. Thus, the substrate W that has undergone the treatment process in the hydrophobization chamber 33 may be changed from hydrophilic to hydrophobic, thereby improving adhesive force to the photoresist film or anti-reflective film.

Further, the cooling chamber 34 may receive the hydrophobized substrate W in the hydrophobization chamber 33 from the first buffer robot 31 and cool the received substrate W. Furthermore, the cooling chamber 34 may receive the heat-treated substrate W from the first main transfer robot 42 and cool the received substrate W. Thus, the substrate W cooled by the cooling chamber 34 may facilitate removal of particles that may be formed on the substrate W by cooling. The cooling chamber 34 may utilize a water cooling method that sprays a cooling liquid directly onto the substrate W, or a thermal conductive cooling method that conducts cold air. Additionally, the cooling chambers 34 may be stacked with each other, and in this case, the cooling chambers 34 may include a greater number than the number illustrated in the drawings.

As one example of such the cooling chamber 34, the cooling chamber 34 may include a frame 34a, a cooling plate 34b, and a support 34c.

The frame 34a has a generally cuboidal shape and provides a space in which the cooling plate 34b and the support 34c are housed. Here, the frame 34a may provide a plurality of seating regions such that the plurality of units formed of the cooling plates 34b and the supports 34c is mounted separately when the cooling plates 34b and the supports 34c are formed as the plurality of units. Furthermore, all four sides of the frame 34a may be provided as open surfaces. Alternatively, the frame 34a may also be formed in a closed configuration such that the surface facing the second buffer robot 35 is not open.

A plurality of cooling plates 34b is provided, which may be stacked on top of each other in the third direction 1Z. The cooling plates 34b are disposed at a certain distance apart from each other. Within each of the cooling plates 34b, a cooling flow path 34bl is formed through which a cooling fluid flows. The cooling fluid may be water. The cooling plate 34b provides a region on which the substrate W is seated, and when the substrate W is seated, the cooling plate 34b cools the substrate W by heat conduction of cold air. The cooling plate 34b is provided with a generally disk shape and has a diameter corresponding to the substrate W. Further, the cooling plate 34b may have a cooling channel flow path 34b1 formed therein through which a cooling fluid may flow. In addition, a notch 34b2 is formed on the edge of the cooling plate 34b. The notch 34b2 may have a shape corresponding to the protrusion formed on the hand of the first main transfer robot 42. Further, the notches 34b2 are provided in a number corresponding to the protrusions formed on the hand of the first main transfer robot 42, and are formed at positions corresponding to the protrusions. In a position in which the hand of the first main transfer robot 42 and the cooling plate 34b are aligned in an up-down direction, when the up-down position of the hand of the first main transfer robot 42 and the cooling plate 34b changes, the substrate W is transferred between the hand of the first main transfer robot 42 and the cooling plate 34b.

A longitudinal direction of the support 34c is the third direction 1Z and the 34c supports a plurality of cooling plates 34b. Within the support 34c, a distribution line (not illustrated) is formed through which the cooling fluid flows. The cooling flow path 34b1 provided in each of the cooling plates 34b is branched from the distribution line (not illustrated). In the support 34c, an inlet port 34cl through which cooling fluid from the outside is introduced from the cooling plate 34b and an outlet port 34c2 through which cooling fluid is discharged to the outside are formed. The distribution line is connected with the inlet port 34cl and the outlet port 34c2.

The second buffer robot 35 transfers the substrate W temporarily loaded in the second buffer 36 after the development is completed to the hand of the index robot 21. Here, the second buffer robot 35 is disposed opposite the first buffer robot 31, with the first buffer 32 and the cooling chamber 34 interposed therebetween, so that only the developed substrate W may be efficiently unloaded. The second buffer robot 35 may be formed such that the hand directly handling the substrate W is movable in the axial direction of each of the first direction 1X, the second direction 1Y, and the third direction 1Z, and rotatable in the axial direction of the third direction 1Z.

The second buffer 36 may receive the substrate W that has been completely developed from the second main transfer robot 92 and temporarily load the received substrate W. In this case, the second buffer 32 may be formed in the form in which a plurality of loading plates is arranged while being vertically spaced apart from each other to mount the plurality of substrates W. Further, the second buffer 36 may be formed with an increased number of loading plates as illustrated, or may include a plurality of units, to increase the loading capacity. Further, the second buffer 36 may be disposed above or below the first buffer 32.

The first transfer chamber 40 is disposed between the liquid treatment chamber 50 and the first heat treatment chamber 60. The first transfer chamber 40 may load and unload the substrate W mounted on the buffer module 30. In addition, the first transfer chamber 40 may load the substrate W loaded from the buffer module 30 to the liquid treatment chamber 50 when the substrate W is liquid treated. Further, the first transfer chamber 40 may load the liquid-treated substrate W from the liquid treatment chamber 50 to the first heat treatment chamber 60. Further, the first transfer chamber 40 may load the heat-treated substrate W in the first heat treatment chamber 60 to the cooling chamber 34. Further, the first transfer chamber 40 may load and unload the cooled substrate W of the cooling chamber 34.

As one example of the first transfer chamber 40, the first transfer chamber 40 may include a first transfer housing 41 and a first main transfer robot 42.

The first transfer housing 41 is schematically formed in a cuboidal shape. The first transfer housing 41 may have a transfer space in which the first main transfer robot 42 is transferred and a communicating region in which the first transfer housing 41 communicates with the liquid treatment chamber 50 and the first heat treatment chamber 60.

The first main transfer robot 42 is disposed on the inner side of the first transfer housing 41. The first main transfer robot 42 may mount the substrate W on a hand 42a to load and unload the substrate W into and from the liquid treatment chamber 50 and the first heat treatment chamber 60, and to load and unload the substrate W into and from the liquid treatment chamber 50. Accordingly, the first main transfer robot 42 may be formed such that the hand 42a directly handling the substrate W is movable in the axial direction of each of the first direction 1X, the second direction 1Y, and the third direction 1Z, and rotatable in the axial direction of each of the first direction 1X, the second direction 1Y, and the third direction 1Z. In this case, the hand 42a of the first main transfer robot 42 may further have a base 42al, support protrusions 42a2, and a support shaft 42a3. The base 42al may have the shape of an annular ring with a portion of the circumference bent. The base 42al has an inner diameter that is larger than the diameter of the substrate W. The base 42al protrudes horizontally on one side from the vertical support axis to support the substrate W in a horizontal state. The support protrusion 42a2 extends inwardly therefrom from the base 42al. The support protrusions 42a2 may be provided in plurality and support an edge region of the substrate W. In one example, four equally spaced support protrusions 42a2 may be provided. Here, each of the support protrusions 42a2 may be configured with a position sensor (not illustrated) that detects the position of the substrate W, and the position sensor may be formed of a photo sensor including a light emitting unit and a light receiving unit. In addition, the first main transfer robot 42 may further include a first transfer unit 43. The first transfer unit 43 may transfer the first main transfer robot 42 in the first direction 1X. Here, the first transfer unit 43 may comprise an actuator for transfer that travels along the guide rail in one path. For example, the first transfer unit 43 may be formed of a linear motor. The first transfer unit 43 is arranged in one straight line toward the first direction 1X to transfer the first main transfer robot 42 in one path. In the present exemplary embodiment, the one path may be formed in a straight line, and the one path may be varied not only in the form of a straight line but also in the form of a mixture of curved and straight lines. Here, the first main transfer robot 42 is provided to be movable along the longitudinal direction of the first transfer chamber 40. In this case, one end facing in a longitudinal direction of the first transfer chamber 40 is adjacent to the buffer module 30, and the other end facing in the longitudinal direction of the first transfer chamber 40 is disposed adjacent to the interface module 70. In this case, an edge exposure chamber 72 is disposed adjacent to the other end of the first transfer chamber 40. Thus, the liquid-treated and heat-treated substrate W is only loaded in by the first main transfer robot 42, and the edge-exposed substrate W is not unloaded by the first main transfer robot 42. Therefore, since the substrate W edge-exposed in the edge exposure chamber 72 does not undergo the unloading process of the first main transfer robot 42, the speed of production of the substrate W is decreased and the production volume of the substrate W is increased.

The liquid treatment chamber 50 forms a liquid film by supplying a liquid onto the substrate. The liquid film may be a photoresist film, an anti-reflective film, or a mixture thereof.

As one example of the liquid treatment chamber 50, the liquid treatment chamber 50 may have a support unit 51, a liquid supply unit 52, a housing 53, and a cup 54.

The support unit 51 is disposed within the treatment space and supports the substrate W. The support unit 51 is configured in the form of a spindle and is provided to rotate the substrate W during liquid treatment.

The liquid supply unit 52 supplies liquid to the substrate W supported on the support unit 51. The liquid supply unit 52 further includes a nozzle for spraying the liquid film at one end and a transfer actuator for transferring the nozzle, to apply the liquid film to the substrate W while varying the position of the nozzle.

The housing 53 is provided in the shape of a generally rectangular parallelepiped. An inlet (not illustrated) through which the substrate W enters and exits is formed on a lateral wall of the housing 53. The inlet may be opened/closed by a door (not illustrated). The cup 54, the support unit 51, and the liquid supply unit 52 are provided in the housing 53. The upper wall of the housing 53 may be provided with a fan filter unit 53a that forms a downward airflow within the housing 53.

The cup 54 has a treatment space of which a top portion is opened. The cup 54 may prevent the liquid scattered during liquid treatment of the substrate W from being scattered onto the inner side of the housing 53. In this case, the cup 54 may be connected with an exhaust port (not illustrated) extending to the outer side of the housing 53 to exhaust fumes and scattered substances inside the treatment space. The liquid treatment chambers 50 may include a plurality of such chambers, stacked on top of each other. Here, the liquid treatment chamber 50 may be implemented in any form that processes a liquid film. For example, the liquid treatment chamber 50 may form a photoresist film or anti-reflective film on a substrate, and may be configured in plurality to form another photoresist film or anti-reflective film on the photoresist film or anti-reflective film. In the present exemplary embodiment, the liquid treatment chamber 50 is illustrated as including a photoresist film application chamber 50a for applying a photoresist film, and an anti-reflective film application chamber 50b used for applying an anti-reflective film.

The first heat treatment chamber 60 includes a first heat treatment housing 61, a first heat treatment heating unit 63, and a first heat treatment transfer plate 64.

The first heat treatment housing 61 is provided in a generally cuboidal shape. A side wall of the first heat treatment housing 61 is formed with an inlet (not illustrated) through which the substrate W enters and exits. The inlet may remain open. Optionally, a door (not illustrated) may be provided to open and close the inlet. The first heat treatment heating unit 63 and the first heat treatment transfer plate 64 are provided within the first heat treatment housing 61. The first heat treatment transfer plate 64 and the first heat treatment heating unit 63 are arranged along the second direction 1Y. In one example, the first heat treatment transfer plate 64 may be positioned closer to the first main transfer robot 42 than the first heat treatment heating unit 63.

The first heat treatment heating unit 63 conducts heat to the substrate W to heat the substrate W.

As one example of the first heat treatment heating unit 63, the first heat treatment heating unit 63 includes a heating plate 63a and a cover 63b.

The heating plate 63a has a generally circular shape when viewed from the top. The heating plate 63a has a larger diameter than the substrate W. A heater 63al is further installed on the heating plate 63a. The heater 63al may be provided as a heating resistor to which a current is applied. Also, the heater 63al may be formed of a thermoelectric element in the form of a plate. The heating plate 63a is provided with lift pins 63a2 movable in an upward and downward direction along the third direction 1Z. The lift pin 63a2 receives the substrate W from the transfer means outside the first heat treatment heating unit 63 and place the substrate W down on the heating plate 63a, or lift the substrate W from the heating plate 63a and transfer the substrate W to the first heat treatment transfer plate 64. In one example, three lift pins 63a2 may be provided. The cover 63b has a lower open space inside.

The cover 63b is positioned on top of the heating plate 63a and is moved in an upward and downward direction by a driver 63b1. The space formed by the cover 63b and the heating plate 63a as the cover 63b is moved is provided as a heating space for heating the substrate W.

The first heat treatment transfer plate 64 is provided with a generally disk shape and has a diameter corresponding to the substrate W. A notch 64a is formed on an edge of the first heat treatment transfer plate 64. The notch 64a may have a shape corresponding to the support protrusions 42a2 formed on the hand 42a of the first main transfer robot 42. Further, the notches 64a are provided in a number corresponding to the number of support protrusions 42a2 formed on the hand 42a, and are formed at locations corresponding to the support protrusions 42a2. At a position in which the hand 42a and the first heat treatment transfer plate 64 are aligned in an up-down direction, when the up-down position of the hand 42a and the first heat treatment transfer plate 64 is changed, the substrate W is transferred between the hand 42a and the first heat treatment transfer plate 64. Further, the first heat treatment transfer plate 64 is mounted on a guide rail 64b, and may be moved between an inner region and an outer region of the first heat treatment housing 61 along the guide rail 64b by a driver 64c. Further, the first heat treatment transfer plate 64 is provided with a plurality of slit-shaped guide grooves 64d. The guide grooves 64d extend from a distal end of the first heat treatment transfer plate 64 to an interior of the first heat treatment transfer plate 64. The guide groove 64d is provided along the second direction 1Y in a longitudinal direction, and the guide grooves 64d are spaced apart from each other along the first direction 1X. The guide grooves 64d prevent the first heat treatment transfer plate 64 and the lift pin 63a2 from interfering with each other when a handover of the substrate W is performed between the first heat treatment transfer plate 64 and the first heat treatment heating unit 63. In this case, cooling of the substrate W is accomplished in the state where the first heat treatment transfer plate 64 on which the substrate W is placed is in contact with the cooling plate 62a. To ensure good heat transfer between the cooling plate 62a and the substrate W, the first heat treatment transfer plate 64 is provided with a material having high thermal conductivity. In one example, the first heat treatment transfer plate 64 may be provided with a metal material.

The first heat treatment chamber 60 as described above may be formed of a plurality of first heat treatment chambers 60, stacked on top of each other or arranged laterally, depending on the type of film and the type of process. In the present exemplary embodiment, the first heat treatment chamber 60 is exemplified as including a photoresist film heat treatment chamber 60a for heat treating a photoresist film, and an anti-reflective film heat treatment chamber 60b for heat treating an anti-reflective film.

The first transfer chamber 40, the liquid treatment chamber 50, and the first heat treatment chamber 60 as described above are utilized as an application module of an application process in which the substrate W is processed by applying the film onto the substrate W. Accordingly, the application module may include the first transfer chamber 40, the liquid treatment chamber 50, and the first heat treatment chamber 60.

The interface module 70 is arranged to be coupled to the first transfer chamber 40. Further, the interface module 70 is disposed opposite the buffer module 30. The interface module 70 edge-exposes the substrate W received from the first transfer chamber 40. Further, the interface module 70 is disposed to be connected with the exposure device 80 to receive the edge-exposed substrate W into the exposure device 80. Further, the interface module 70 unloads the substrate W after exposure in the exposure device 80 and temporarily stores the substrate W.

As one example of such the interface module 70, the interface module 70 may include a first interface robot 71, an edge exposure chamber 72, an interface first buffer 73, a second interface robot 74, an interface second buffer 75, a defect inspection unit 76, and an interface frame 77.

The first interface robot 71 may load the edge-exposed substrate W by the edge exposure chamber 72 to the exposure device 80. Further, the first interface robot 71 may load the edge-exposed substrate W by the edge exposure chamber 72 to the interface first buffer 73 side, and temporarily load the substrate W into the interface first buffer 73. The first interface robot 71 may be formed such that the hand directly handling the substrate W is movable in the axial direction of each of the first direction 1X, the second direction 1Y, and the third direction 1Z and rotatable in the axial direction of the third direction 1Z.

The edge exposure chamber 72 may receive the heat-treated and liquid-treated substrate W from the first main transfer robot 42 of the first transfer chamber 40, and may expose the area near the edge of the received substrate W to reduce particles near the edge that may be generated in subsequent processing.

As one example of such the edge exposure chamber 72, the edge exposure chamber 72 may include an edge exposure housing 72a, an edge exposure support part 72b, and an edge exposure source 72c.

The edge exposure housing 72a is provided in a generally cuboidal shape. The edge exposure housing 72a has a treatment space for edge-exposing the substrate W formed therein, and the treatment space is provided with the edge exposure support part 72b and the edge exposure source 72c. Furthermore, the edge exposure housing 72a is formed with an inlet 72al through which the substrate W before edge exposure is received from the hand of the first main transfer robot 42, and an outlet 72a2 through which the substrate W after edge exposure is discharged by the first interface robot 71. In this case, the inlet 72al serves as a passage through which the hand 42a of the first main transfer robot 42 is moved, and the outlet 72a2 serves as a passage through which the hand 71 of the first interface robot 71 is moved. Here, when viewed from the top to the bottom, the wall body on which the inlet 72al of the edge exposure housing 72a is provided and the wall body on which the outlet 72a2 is provided are arranged perpendicular to each other. Thus, the first interface robot 71 is not arranged along an extension of the first direction 1X, so that the space occupied within the interface frame 77 is minimized, which may increase the output per unit area of the substrate processing apparatus.

The edge exposure support unit 72b is disposed on the inside of the edge exposure housing 72a and may be formed to be rotatable while supporting the substrate W.

The edge exposure source 72c is disposed above the edge exposure support unit 72b and may irradiate the edge of the substrate W with light. In this case, the edge exposure source 72c is disposed with a light source for emitting ultraviolet light to the area near the edge of the substrate W rotated by the edge exposure support unit 72b, and may irradiate the edge of the substrate W with ultraviolet light. In this case, the light source may be configured as a UV lamp or a UV LED. Furthermore, the edge exposure source 72c may be mounted on a transfer robot (not illustrated) having two or more degrees of freedom to adjust its position so that the exposure position is varied, thereby adjusting the exposure width when exposing the edge of the substrate W.

Since the edge exposure chamber 72 is located between the exposure device 80 and the first main transfer robot 42, the edge exposure chamber 72 may receive the substrate W from the first main transfer robot 42 and edge expose the substrate W, and then the first interface robot 71 may load the edge exposed substrate W directly to the exposure device 80. Thus, the process of unloading the edge-exposed substrate W by the first main transfer robot 42 is omitted, thereby increasing the yield of substrate W. In this case, the edge exposure chamber 72 may also be temporarily loaded with the substrate W before being discharged to the exposure device 80. Further, the edge-exposed substrate W in the edge exposure chamber 72 may be transferred by the first interface robot 71 to the interface first buffer 73 for temporary loading. Here, the first interface robot 71 may increase the yield of the substrate W by allowing the substrate W temporarily loaded in the interface first buffer 73 to enter directly to the exposure device 80 when the substrate W is available for exposure in the exposure device 80.

Additionally, the edge exposure chamber 72 may include a plurality of edge exposure chambers, and the plurality of edge exposure chambers 72 may be stacked. In this case, the first main transfer robot 42 may transfer each of the plurality of substrates W to the edge exposure chamber 72 such that the plurality of substrates W are edge-exposed, thereby ensuring that the substrates W are always ready to enter when the exposure device 80 is available for exposing the substrate W. Additionally, the edge exposure chamber 72 may be disposed above or below the interface first buffer 73.

On the other hand, when the edge exposure chamber 72 does not utilize a light source but instead utilizes a method of spraying a solvent, such as a thinner, the size of the equipment may be increased compared to the method utilizing a light source, which may increase the production cost, and the yield of the substrate W may be lower due to the additional process, because the process of discharging the solvent to the outside and the process of removing the solvent needs to be further considered.

The interface first buffer 73 receives the substrate W that has been edge-exposed by the edge exposure chamber 72 from the first interface robot 71 and temporarily loads the substrate W. In this case, the interface first buffer 73 may be formed in the form in which stacking plates are stacked in multiple stages for mounting a plurality of edge-exposed substrates W. As such, the interface first buffer 73 temporarily loads the edge-exposed substrate W to ensure the substrate is unloaded so that the edge exposure chamber 72 is capable of edge-exposing the substrate W at all times, and to ensure that the substrate W is received into the exposure device 80 when the exposure device 80 is available to expose the substrate W. Additionally, the interface first buffer 73 may be disposed perpendicular to the edge exposure chamber 72 when viewed in a plane. For example, the interface first buffer 73 may be disposed above the edge exposure chamber 72, or may be disposed under the edge exposure chamber 72. In this case, the outlet 72a2 of the edge exposure chamber 72 and the entrance port of the interface first buffer 73 may be provided in the same direction as each other in which the substrate W enters and exits. Thus, when the first interface robot 71 transfers the substrate W from the edge exposure chamber 72 to the interface first buffer 73, the travel path of the substrate W is minimized, which may reduce the transfer time. Furthermore, since the edge exposure chamber 72 and the interface first buffer 73 are arranged at the top and bottom, the space occupied is minimized, which may increase the output per unit area of the substrate processing apparatus according to the present invention.

The second interface robot 74 loads the substrate W after the exposure process has been finalized by the exposure device 80 into the interface second buffer 75. The second interface robot 74 may be formed such that the hand directly handling the substrate W is movable in the axial direction of each of the first direction 2X, the second direction 1Y, and the third direction 1Z and rotatable in the axial direction of the third direction 1Z.

Here, the second interface robot 74 is disposed opposite the first interface robot 71, with the edge exposure chamber 72 and the interface first buffer 73 and the interface second buffer 75 interposed therebetween. Thus, the second interface robot 74 is capable of only driving to unload the substrate W from the interface first buffer 73 without interference with the first interface robot 71, thereby increasing the transfer efficiency of the substrate W and thus increasing the yield of the substrate W.

The interface second buffer 75 receives the substrate W from the second interface robot 74 and temporarily stacks the substrate W after the substrate W has been exposed by the exposure device 80. In this case, the interface second buffer 75 may be formed in the form in which the stacking plates are stacked in multiple stages so that the plurality of substrates W exposed by the exposure device 80 may be mounted. By temporarily loading the substrate W exposed by the exposure device 80, the interface second buffer 75 prepares the substrate W for immediate delivery to the development module side by the second main transfer robot 92.

The defect inspection unit 76 may be disposed along the path of the substrate W being loaded from the first transfer chamber 40 to the edge exposure chamber 72. In one example, the defect inspection unit 76 may be disposed on an inner side of the edge exposure housing 72a. The defect inspection unit 76 may include a laser line scanner to inspect the flatness of the surface or a vision inspection device to inspect whether image information of the surface is changed. The defect inspection unit 76 may scan the surface of the substrate W loaded into the edge exposure chamber 72 for edge exposure to inspect defects, such as depressions or protruding of the surface of the substrate W, or particles on the surface of the substrate W. In this case, when the defect inspection unit 76 detects a defect in the substrate W during inspection, the cause of the defect may be analyzed by discharging the substrate W to the first transfer chamber 40, the buffer module 30, the index module 20, and the load port 10, or recording the defect in a process controller. Thus, the defect inspection unit 76 may increase the yield of the substrate W by detecting defective substrates in advance.

The interface frame 77 is schematically formed as a frame with a cuboidal shape, and is provided with the first interface robot 71, the edge exposure chamber 72, the interface first buffer 73, the second interface robot 74, the interface second buffer 75, and the defect inspection unit 76 inside. The interface frame 77 may be equipped with a fan (not illustrated) at the top to form an airflow inside to prevent particles from flowing in and out of the chambers.

The exposure device 80 emits light according to the shape of the predesigned circuit pattern with a mask (not illustrated) disposed in the upper space of the substrate W, thereby forming the predesigned circuit pattern in the exposure area of the photoresist applied to the substrate W. The exposure device 80 is in conjunction with the interface module 70, receives the substrate W before exposure from the first interface robot 71, exposes the substrate W, and unloads the exposed substrate W to the second interface robot 74. In this case, the first interface robot 71 loads the pre-exposure substrate W temporarily loaded in the interface first buffer 73 into the exposure device 80, and the second interface robot 74 the post-exposure substrate W to the interface second buffer 75 and temporary loads the substrate W.

The second transfer chamber 90 may load and unload the post-exposure substrate W received in the interface second buffer 75 to and from the development chamber 100. Further, the second transfer chamber 90 may load and unload the substrate W developed by the development chamber 100 to and from the second heat treatment chamber 110. Further, the second transfer chamber 90 may unload the substrate W that has been heat treated in the second heat treatment chamber 110 to the second buffer 36 of the buffer module 30. Further, the second transfer chamber 90 may be formed by stacking with the first transfer chamber 40. Here, the second transfer chamber 90 is disposed under the first transfer chamber 40, and may also be disposed above the first transfer chamber 40 depending on the processing efficiency of the process or a change in the process sequence.

As one example of the second transfer chamber 90, the second transfer chamber 90 may include a second transfer housing 91, and a second main transfer robot 92.

The second transfer chamber 90 is substantially the same as the first transfer chamber 40. Accordingly, a configuration of the same structure is illustrated in the drawings with superimposed drawing symbols, and the detailed description thereof will be replaced by the foregoing description, and the following description will focus on the differences with respect to the first transfer chamber 40.

Here, the second transfer housing 91 is formed substantially the same as the first transfer housing 41, the second main transfer robot 92 is formed substantially the same as the first main transfer robot 42, and a second transfer unit 93 is formed substantially the same as the first transfer unit 43.

The second transfer housing 91 may be disposed under the first transfer housing 41. Thus, the second transfer housing 91 may increase the yield of the substrate W by enabling the substrate W to be developed and heat treated by the exposure device 80 in the shortest path during development and heat treatment.

The second main transfer robot 92 is disposed on the inner side of the second transfer housing 91, and is capable of mounting the substrate W on a hand 92a to load and unload the mounted substrate W into and from the development chamber 100 and the second heat treatment chamber 110, and to load the developed and second heat treated substrate W into the second buffer 36. Here, the hand 92a of the second main transfer robot 92 may be configured to have a base 92a1, a support protrusion 92a2, and a support shaft 92a3 identically to the form of the hand 42a of the first main transfer robot 42 described above, to support the substrate W, and a redundant description thereof will be omitted. Furthermore, the second transfer unit 93 may be formed of the same structure as the first transfer unit 43 described above, and a redundant description thereof will be omitted. The second transfer unit 93 may transfer the second main transfer robot 92 in the first direction 2X.

The development chamber 100 may receive the substrate W that has been exposed by the exposure device 80 and the edge exposure chamber 72 from the second main transfer robot 92, and may develop the exposed substrate W. The development chambers 100 may include a plurality of development chambers and may be stacked on top of each other or disposed adjacent to each other.

As one example of the development chamber 100, the development chamber 100 may include a second rotation unit 101, a developer supply unit 102, and a development housing 103.

The second rotation unit 101 supports the substrate W and is capable of rotating the substrate W.

The developer supply unit 102 supplies the substrate W developer from the upper part of the second rotation unit 101. Here, as one example of the developer, the developer may be formed of an alkali solution and a surfactant. Thus, the substrate W is rotated by the developer supply unit 102 and the photoresist film is developed by the developer. In this case, the developer supply unit 102 may be repositioned by a transfer body (not illustrated) so that the developer is supplied to the entire upper surface of the substrate W.

The development housing 103 forms a developer treatment space in which the second rotation unit 101 and the developer supply unit 102 are mounted.

However, the development chamber 100 is not limited to the above scheme, and the development chamber 100 may be implemented in various variations, such as a dip method in which the substrate W is immersed in a bath containing a developer, or a spray method in which the developer is sprayed onto the substrate W with a nozzle. Further, the development chamber 100 may be formed stacked with the liquid treatment chamber 50. Furthermore, the development chamber 100 may include a plurality of development chambers stacked on top of each other.

The second heat treatment chamber 110 may receive the substrate W developed by the development chamber 100 from the second main transfer robot 92 and perform a heat treatment process including a cooling process and a heating process. Furthermore, the second heat treatment chamber 110 may be formed of a plurality of second heat treatment chambers stacked on top of each other. In this case, the second heat treatment chamber 110 may be disposed below the first heat treatment chamber 60.

The second heat treatment chamber 110 may include a second heat treatment housing 111, a second heat treatment heating unit 113, and a second heat treatment transfer plate 114.

Here, the second heat treatment housing 111 is formed substantially the same as the first heat treatment housing 61, the second heat treatment heating unit 113 is formed substantially the same as the first heat treatment heating unit 63, and the second heat treatment transfer plate 114 is formed substantially the same as the first heat treatment transfer plate 64. Accordingly, hereinafter, the configuration of the same structure will be illustrated by same reference numerals on the drawings, and the detailed description will be replaced by the foregoing description, and the differences from the first heat treatment chamber 60 will be emphasized hereinafter.

The second heat treatment housing 111 houses the second heat treatment heating unit 113 and the second heat treatment transfer plate 114 inside.

The second heat treatment heating unit 113 may have a second heat treatment heating plate 113a and a second heat treatment cover 113b, in which case the second heat treatment heating plate 113a may have a second heat treatment heater 113al and a second heat treatment lift pin 113a2. Further, the second heat treatment cover 113b may be moved in an upward and downward direction by a second heat treatment driver 113b1.

The second heat treatment transfer plate 114 may have a second notch 114a corresponding to the support protrusion formed on the hand of the second main transfer robot 92, may be mounted on a second guide rail 114b on which a second driver 114c is driven, and may be provided with a plurality of slit-shaped second guide grooves 114d.

As such, the second heat treatment chamber 110 may be configured substantially the same as the first heat treatment chamber 60 to heat treat the substrate W.

In this case, the plurality of second heat treatment chambers 110 may be set with different temperature values at which the substrate W is heat treated, so that the plurality of second heat treatment chambers 110 may be formed to include a soft heat treatment chamber 110a and a hard heat treatment chamber 110b depending on the temperature value. Here, the soft heat treatment chamber 110a may heat the substrate W such that some of the organic solvent of the photoresist film remains, thereby maintaining the adhesion of the photoresist film to the substrate W, and the hard heat treatment chamber 110b may heat the substrate W heated by the soft heat treatment chamber 110a to a temperature higher than the temperature of the soft heat treatment chamber 110a to completely remove the organic solvent, thereby increasing the resistance to etching in a subsequent etching process.

Since the second transfer chamber 90, the development chamber 100, and the second heat treatment chamber 110 are utilized in the development module of the developing process for developing the substrate W as described above, the development module may include the second transfer 90, the development chamber 100, and the second heat treatment chamber 110.

The process controller (not illustrated) is a device that controls the driving of the load port 10, the index module 20, the buffer module 30, the first transfer chamber 40, the liquid treatment chamber 50, the first heat treatment chamber 60, the interface module 70, the exposure device 80, the second transfer chamber 90, the development chamber 100, and the second heat treatment chamber 110 for process processing and substrate transfer according to a preset scheduling. Accordingly, in the present invention, the process processing driving and the substrate transfer driving are controlled by the process controller, and accordingly, a detailed description of the specific control drive of the process controller will be omitted, and the driving of the process processing and the substrate transfer will be emphasized.

The following describes the substrate processing method of the substrate processing apparatus as described above.

In the following description, the “substrate processing method before exposure” and the “substrate processing method after exposure” will be described respectively.

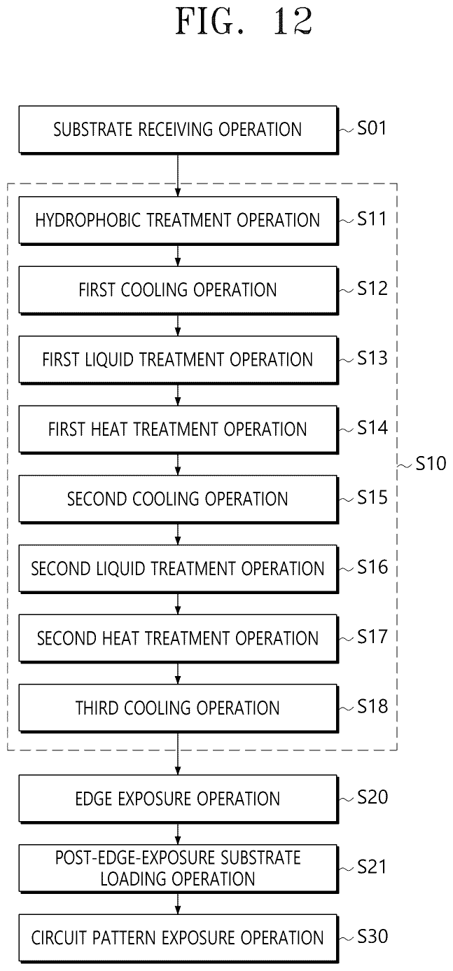

FIG. 12 is a flowchart of a substrate processing method before exposure according to an exemplary embodiment of the present invention.

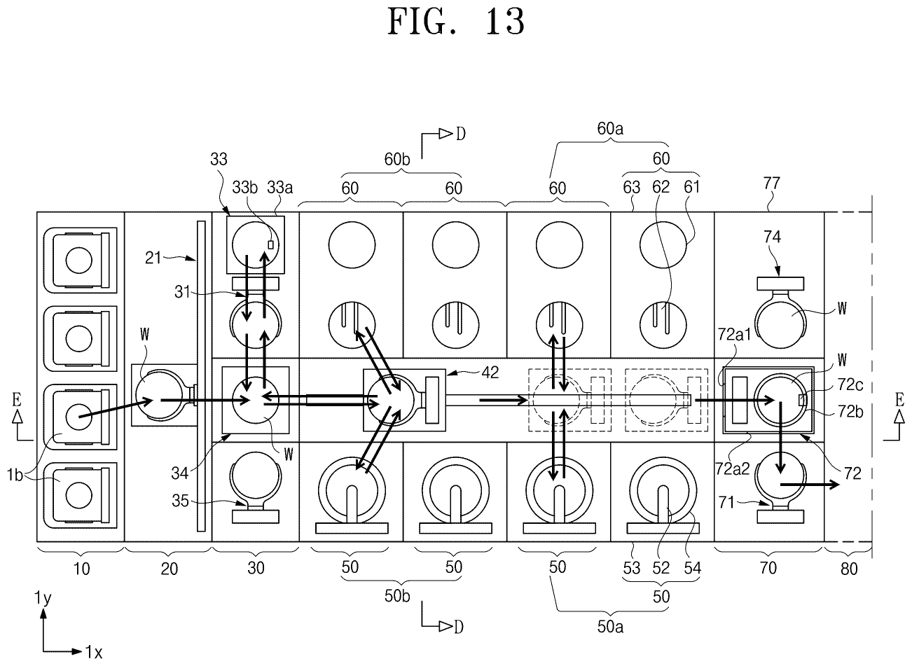

FIG. 13 is a diagram schematically illustrating a substrate transfer path according to the sequence of the substrate processing method of FIG. 12.

Referring further to FIGS. 12 and 13, the “substrate processing method before exposure” of the present invention may include a substrate receiving operation S01, a film treatment operation S10, an edge exposure operation S20, a post-edge-exposure substrate loading operation S21, and a circuit pattern exposure operation S30.

First, in the substrate receiving operation S01, the index robot 21 of the index module 20 transfers the substrate W loaded in by the container of the load port 10 to the first buffer 32.

Next, the film treatment operation S10 may proceed including a hydrophobic treatment operation S11, a first cooling operation S12, a first liquid treatment operation S13, a first heat treatment operation S14, a second cooling operation S15, a second liquid treatment operation S16, a second heat treatment operation S17, and a third cooling operation S18.

In the hydrophobic treatment operation S11, the first buffer robot 31 loads the substrate W in the first buffer 32 into the hydrophobization chamber 33. In this case, the hydrophobization chamber 33 treats the received hydrophilic substrate W to be hydrophobic. Here, the hydrophobization chamber 33 may treat the substrate W to be hydrophobic by using HMDS (Hecamethyldisilazane) vapor gas.

Then, in the first cooling operation S12, the first buffer robot 31 loads the substrate W hydrophobically treated in the hydrophobic treatment operation S11 into the cooling chamber 34. In this case, the cooling chamber 34 cools the received substrate W to remove particles that may be present on the substrate W, thereby reducing the defect rate of the substrate W.

Next, in the first liquid treatment operation S13, the first main transfer robot 42 moves to the cooling chamber 34 side by the first transfer unit 43, mounts the substrate W in the cooling chamber 34 onto the hand 42a, and loads the mounted substrate W into the support unit 51 of the anti-reflective film application chamber 50b. In this case, in the anti-reflective film application chamber 50b of the liquid treatment chamber 50, an anti-reflective film is formed on the upper surface of the substrate W by the application method as described above.

Next, in the first heat treatment operation S14, the first main transfer robot 42 transfers the substrate W treated with the anti-reflective film to the first heat treatment transfer plate 64 of the anti-reflective film heat treatment chamber 60b according to the treatment process. More specifically, the first main transfer robot 42 seats the substrate W on the first heat treatment transfer plate 64, and the first heat treatment transfer plate 64 moves in one direction to seat the substrate W on the lift pin 63a2 of the heating plate 63a. The substrate W seated on the lift pin 63a2 is in close contact with the heating plate 63a by the descent of the lift pin 63a2, and is heated by the heated heating plate 63a to heat treat the anti-reflective film.

Then, in the second cooling operation S15, the first heat treatment transfer plate 64 transfers the substrate W toward the first main transfer robot 42 in the state where the substrate W is raised by the ascent of the lift pin 63a2, and then the first main transfer robot 42 receives the substrate W heat treated in the anti-reflective film heat treatment chamber 60b from the first heat treatment transfer plate 64, and loads the received substrate W back to the cooling chamber 34. In this case, the cooling chamber 34 cools the substrate W in the same manner as described above to remove the particles.

Then, in the second liquid treatment operation S16, the first main transfer robot 42 moves to the side of the cooling chamber 34 to load the substrate W in the cooling chamber 34 into the support unit 51 of the photoresist film application chamber 50a. In this case, the photoresist film application chamber 50a forms a photoresist film on the upper surface of the substrate W by the application method as described above.

Next, in the second heat treatment operation S17, the first main transfer robot 42 transfers the substrate W treated with the photoresist film to the first heat treatment transfer plate 64 of the photoresist film heat treatment chamber 60a. In this case, the first main transfer robot 42 seats the substrate W on the first heat treatment transfer plate 64, and the first heat treatment transfer plate 64 moves in one direction to seat the substrate W on the lift pin 63a2 of the heating plate 63a. The substrate W seated on the lift pin 63a2 is in close contact with the heating plate 63a by the descent of the lift pin 63a2, and is heated by the heated heating plate 63a to heat treat the photoresist film.

Next, in the third cooling operation S18, the first heat treatment transfer plate 64 transfers the substrate W toward the first main transfer robot 42 in the state where the substrate W is raised by the ascent of the lift pin 63a2, and then first main transfer robot 42 receives the substrate W heat treated in the photoresist film heat treatment chamber 60a from the first heat treatment transfer plate 64, and loads the received substrate W back into the cooling chamber 34 again. In this case, the cooling chamber 34 cools the substrate W in the same manner as described above to remove the particles. In this case, the process from the first liquid treatment operation S13 to the second cooling operation S15 for heat treatment after applying the anti-reflective film described above may be performed in a different order from the process from the second liquid treatment operation S16 to the third cooling operation S18 for heat treatment after applying the photoresist film. Furthermore, the process from the first liquid treatment operation S13 to the second cooling operation S15 and the process from the second liquid treatment operation S16 to the third cooling operation S18 may be alternated with each other and performed many times to form photoresist films and anti-reflective films in multiple layers.

Next, in the edge exposure operation S20, the first main transfer robot 42 loads the substrate W cooled in the cooling chamber 34 into the edge exposure chamber 72 through the inlet 72al of the edge exposure chamber 72. In this case, the edge exposure chamber 72 exposes the edge of the substrate W in an edge exposure method as described above. In this case, the first main transfer robot 42 loads the substrate W into the inlet 72al of the edge exposure chamber edge exposure chamber 72 on a line extending along the longitudinal direction of the first transfer chamber 40. Thus, the first main transfer robot 42 may load the substrate W in straightly and rapidly moving state, thereby reducing the transfer time.

Furthermore, in the edge exposure operation S20, when the substrate W is loaded into the edge exposure chamber 72, the defect inspection unit 76 further performs the operation of inspecting the substrate W for defects as described above, so that the yield of the substrate W may be increased by recognizing the defective substrate W in advance.

Next, in the post-edge-exposure substrate loading operation S21, the first interface robot 71 loads the edge-exposed substrate W into the interface first buffer 73 through the outlet 72a2 of the edge exposure chamber 72. In this case, the first main transfer robot 42 is controlled not to be engaged in the process of unloading the substrate W from the edge exposure chamber 72 after the substrate W has been loaded into the edge exposure chamber 72. During the loading and the unloading of the edge-exposed substrate W by the first interface robot 71, the first main transfer robot 42 moves to the treatment modules for liquid treatment and heat treatment and is engaged in the process of transferring the substrates W, thereby increasing the production rate of the substrates W. In this way, in the substrate loading operation S21 after edge exposure, the first main transfer robot 42 does not proceed with the process of transferring the edge-exposed substrates W, thereby increasing the production rate of the substrates W and thus increasing the production volume of the substrates W.

Next, in the circuit pattern exposure operation S30, the first interface robot 71 transfers the substrate W temporarily loaded in the interface first buffer 73 to the exposure device 80 when the exposure device 80 is available for exposure treatment. Then, the exposure device 80 exposes the photoresist film of the substrate W in the form of a circuit pattern while the mask is positioned on the upper surface of the substrate W as described above.

In this way, in the substrate processing apparatus and the substrate processing method of the present invention, since the process of transferring the substrate W loaded into the edge exposure chamber 72 by the first main transfer robot 42 is omitted, the processing speed of the substrate W may be increased, thereby increasing the production volume of the substrate W. To further explain this by way of a comparative example, considering a comparative example in which the liquid-treated and heat-treated substrate W is edge-exposed in an edge-exposure chamber (not illustrated) adjacent to the liquid-treatment chamber 50 or the first heat-treatment chamber 60 during edge-exposure, not at the location illustrated in the drawing, there needs to a process of transferring the edge-exposed substrate W to the interface module 70 by the first main transfer robot 42. In this case, it is assumed that the production rate of the substrate W of the substrate processing apparatus according to the comparative example is 300 sheets per reference hour. In contrast, in the substrate processing apparatus and the substrate processing method of the present invention, the process of transferring the edge-exposed substrate W by the first main transfer robot 42 is omitted, so that it is expected to produce 378 sheets per reference hour.

On the other hand, the substrate W treated by the above-mentioned “substrate processing method before exposure” is subjected to the “substrate processing method after exposure”.

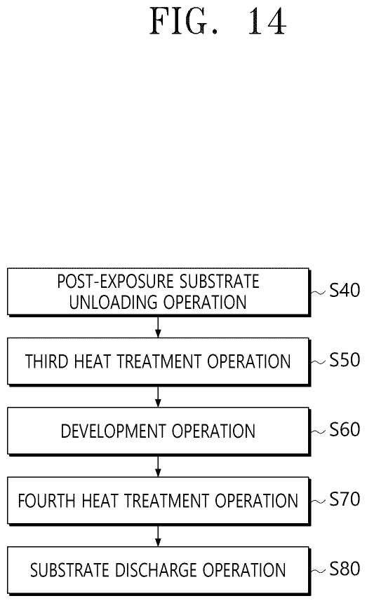

FIG. 14 is a flowchart of the substrate processing method after exposure according to the exemplary embodiment of the present invention.

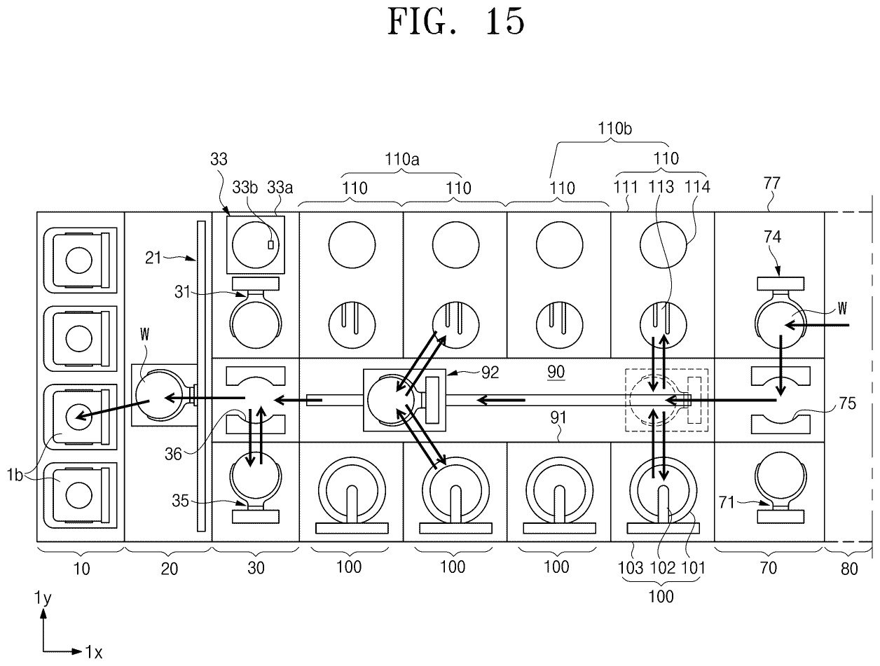

FIG. 15 is a diagram schematically illustrating a substrate transfer path according to the sequence of the substrate processing method of FIG. 14.

Referring further to FIGS. 14 and 15, a “substrate processing method after exposure” according to the exemplary embodiment of the present invention may include a post-exposure substrate unloading operation S40, a third heat treatment operation S50, a development operation S60, a fourth heat treatment operation S70, and a substrate discharge operation S80.

First, in the post-exposure substrate unloading operation S40, the second interface robot 74 loads the substrate W with the circuit pattern exposed by the exposure device 80 into the interface second buffer 75.

Then, in the third heat treatment operation S50, the second interface robot 74 unloads the substrate W from the interface second buffer 75 and loads the substrate W into the second heat treatment chamber 110 to heat treat the substrate W. In the third heat treatment operation S50, the heat treatment may be performed in the soft heat treatment chamber 110a. In this case, the second main transfer robot 92 seats the substrate W on the second heat treatment transfer plate 114, and the second heat treatment transfer plate 114 moves in one direction to seats the substrate W on the second heat treatment lift pin 113a2 of the second heat treatment heating plate 113a. The substrate W seated on the second heat treatment lift pin 113a2 is in close contact with the second heat treatment heating plate 113a by the descent of the second heat treatment lift pin 113a2, and is heated by the heated second heat treatment heating plate 113a to heat treat the substrate W. On the other hand, in the third heat treatment operation S50, after the heat treatment process of heating the substrate W is carried out, heat treatment of cooling the substrate W may be carried out as necessary. In this case, the substrate W may be cooled by a cooling plate (not illustrated) within the second heat treatment chamber 110, or the substrate W may be cooled by the process of transferring the substrate W to the cooling chamber 34 described above. In this case, when the substrate W is transferred to the cooling chamber 34, the second heat treatment transfer plate 114 transfers the substrate W toward the second main transfer robot 92 in the state where the substrate W is raised by the ascent of the second heat treatment lift pin 113a2, and then the second main transfer robot 92 receives the substrate W from the second heat treatment transfer plate 114 and transfers the substrate W to the second buffer 36 of the buffer module 30. The second buffer robot 35 may then load the substrate W loaded in the second buffer 36 into the cooling chamber 34 to cool the substrate W. The cooled substrate W may then be transferred to the second buffer 36 by the second buffer robot 35, and the substrate W transferred to the second buffer 36 may be transferred to the hand of the second main transfer robot 92.

Next, in the development operation S60, the second heat treatment transfer plate 114 transfers the substrate W toward the second main transfer robot 92 in the state where the substrate W is raised by the ascent of the second heat treatment lift pin 113a2, and then the second main transfer robot 92 receives the substrate W from the second heat treatment transfer plate 114 and loads the substrate W into the second rotation unit 101 of the developing chamber 100. In this case, the development chamber 100 develops the substrate W in the same manner as described above.

Then, in the fourth heat treatment operation S70, the second main transfer robot 92 loads the developed substrate W in the development chamber 100 to the second heat treatment chamber 110, and the transferred substrate W is heat treated in the second heat treatment chamber 110. In the third heat treatment operation S70, heat treatment may be performed in the hard heat treatment chamber 110b described above. In this case, the second main transfer robot 92 seats the substrate W on the second heat treatment transfer plate 114, and the second heat treatment transfer plate 114 moves in one direction to seats the substrate W on the second heat treatment lift pin 113a2 of the second heat treatment heating plate 113a. The substrate W seated on the second heat treatment lift pin 113a2 is in close contact with the second heat treatment heating plate 113a by the descent of the second heat treatment lift pin 113a2, and is heated by the heated second heat treatment heating plate 113a to heat treat the substrate W. In the fourth heat treatment operation S70, by heat treating the substrate W at a higher temperature than the third heat treatment operation S50, the remaining developer may be completely removed. On the other hand, in the fourth heat treatment operation S70, after the heat treatment process of heating the substrate W is carried out, a heat treatment of cooling the substrate W may be further carried out as needed. In this case, the substrate W may be cooled by a cooling plate (not illustrated) in the second heat treatment chamber 110, or the substrate W may be cooled through the process of transferring the substrate W to the cooling chamber 34 described above. In this case, when the substrate W is transferred to the cooling chamber 34, the second heat treatment transfer plate 114 transfers the substrate W toward the second main transfer robot 92 in the state where the substrate W is raised by the ascent of the second heat treatment lift pin 113a2, and then the second main transfer robot 92 receives the substrate W from the second heat treatment transfer plate 114 and transfers the substrate W to the second buffer 36 of the buffer module 30. The second main transfer robot 92 then loads the heat-treated substrate W into the second buffer 36, and the second buffer robot 35 may load the substrate W loaded into the second buffer 36 into the cooling chamber 34 to cool the substrate W. The cooled substrate W may then be transferred to the second buffer 36 by the second buffer robot 35.

Next, in the substrate discharge operation S80, the index robot 21 transfers the substrate W temporarily loaded in the second buffer 36 to the load port 10. Subsequently, the substrate W discharged from the load port 10 is transferred to the subsequent processing facility (not illustrated) while being mounted in the container 1b.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

1. A substrate processing apparatus comprising:
an index module;
a buffer module;
a treatment module; and
an interface module,
wherein the index module includes:
a load port in which a container receiving a substrate is placed; and
an index frame provided with an index robot for transferring the substrate between the container placed in the load port and the buffer module,
the buffer module is provided with a buffer in which the substrate is placed,
the treatment module includes:
a liquid treatment chamber for liquid treating the substrate loaded from the buffer module;
a heat treatment chamber for heat treating the substrate received from the buffer module; and
a transfer chamber disposed between the liquid treatment chamber and the heat treatment chamber, and provided with a main transfer robot for transferring substrates to the buffer module, the liquid treatment chamber, and the heat treatment chamber, respectively,
the interface module includes:
an interface frame positioned between the treatment module and an external exposure device;
an edge exposure chamber disposed within the interface frame and performing edge exposure processing on the substrate; and
an interface robot disposed within the interface frame and transferring the substrate, and
each of the main transfer robot and the interface robot loads or unloads the substrate into or from the edge exposure chamber.

2. The substrate processing apparatus of claim 1, wherein the main transfer robot is provided to load the substrate into the edge exposure chamber, and
the interface robot is provided to unload the substrate loaded into the edge exposure chamber.

3. The substrate processing apparatus of claim 2, wherein the main transfer robot is provided not to unload the substrate within the edge exposure chamber.

4. The substrate processing apparatus of claim 1, wherein the treatment module further includes:
an application module for performing an application process on the substrate; and
a development module for performing a developing process on the substrate,
the application module and the development module each include the liquid treatment chamber, the heat treatment chamber, and the main transfer robot,
the application module and the development module are provided to be stacked, and
the main transfer robot provided in the application module is provided to transfer the substrate to the edge exposure chamber.

5. The substrate processing apparatus of claim 1, wherein the edge exposure chamber includes:
an edge exposure housing having a treatment space;
an edge exposure support unit disposed within the treatment space of the edge exposure housing and supporting the substrate; and
an exposure source disposed within the treatment space of the edge exposure housing and irradiating an edge of the substrate with light, and
the edge exposure housing further includes an inlet provided as a passageway for the main transfer robot to be moved into the treatment space, and an outlet provided as a passageway for the interface robot to be moved into the treatment space.

6. The substrate processing apparatus of claim 5, wherein a wall body in which the inlet is formed and a wall body in which the outlet is formed are disposed perpendicularly to each other.

7. The substrate processing apparatus of claim 5, wherein the interface module further includes an interface buffer for loading the substrate unloaded from the edge exposure chamber by the interface robot, and
the interface buffer is disposed in an upper space or a lower space of the edge exposure chamber.

8. The substrate processing apparatus of claim 7, wherein the outlet of the edge exposure chamber and an entrance port of the interface buffer have the same direction in which the substrate enters and exits.

9. The substrate processing apparatus of claim 7, wherein the interface buffer includes:
an interface first buffer provided for loading a substrate unloaded from the edge exposure chamber; and
an interface second buffer provided for loading, by the interface robot, the substrate exposed by an exposure device.

10. The substrate processing apparatus of claim 7, wherein the interface robot further includes:
a first interface robot for unloading the substrate edge-exposed in the edge exposure chamber and loading the substrate into the interface first buffer, and for transferring the substrate loaded in the interface first buffer to the exposure device; and
a second interface robot disposed opposite the first interface robot with the edge exposure chamber interposed therebetween, and provided for loading substrate exposed by the exposure device to the interface second buffer.

11. The substrate processing apparatus method of claim 10, wherein the second interface robot is provided in a position opposite to a direction in which the outlet of the edge exposure housing is formed.

12. The substrate processing apparatus of claim 5, wherein the interface module further includes a defect inspection unit which is installed in a path for loading the substrate from the transfer chamber to a side of the edge exposure chamber, and inspects a defect of the substrate loaded into the edge exposure chamber.

13. The substrate processing apparatus of claim 1, wherein the main transfer robot is provided to be movable along a longitudinal direction of the transfer chamber,
one end in the longitudinal direction of the transfer chamber is adjacent to the buffer module,
the other end in the longitudinal direction of the transfer chamber is adjacent to the interface module, and
the edge exposure chamber is positioned adjacent the other end of the transfer chamber.

14-19. (canceled)

20. A substrate processing apparatus comprising an application module that performs an application process on a substrate, and a development module that performs a development process on a substrate,
wherein the application module and the development module each include the liquid treatment chamber, the heat treatment chamber, and the main transfer robot,
the application module and the development module are provided to be stacked, and
the main transfer robot provided in the application module is provided to transfer the substrate to the edge exposure chamber,
the main transfer robot is provided to be movable along a longitudinal direction of the transfer chamber, one end in the longitudinal direction of the transfer chamber is adjacent to the buffer module, the other end in the longitudinal direction of the transfer chamber is adjacent to the interface module, and the edge exposure chamber is positioned adjacent the other end of the transfer chamber,
the edge exposure chamber includes: an edge exposure housing having a treatment space; an edge exposure support unit disposed within the treatment space of the edge exposure housing and supporting the substrate; and an exposure source disposed within the treatment space of the edge exposure housing and irradiating an edge of the substrate with light, and the edge exposure housing further includes an inlet provided as a passageway for the main transfer robot to be moved into the treatment space, and an outlet provided as a passageway for the interface robot to be moved into the treatment space, a wall body in which the inlet is formed and a wall body in which the outlet is formed are disposed perpendicularly to each other, and the outlet of the edge exposure chamber and an entrance port of the interface buffer have the same direction in which the substrate enters and exits, and
the interface module further includes an interface buffer for loading the substrate unloaded from the edge exposure chamber by the interface robot, and
the interface buffer is disposed in an upper space or a lower space of the edge exposure chamber, and includes: an interface first buffer provided for loading a substrate unloaded from the edge exposure chamber; and an interface second buffer provided for loading, by the interface robot, the substrate that has been exposed by an exposure device,
the interface robot includes: a first interface robot for unloading the substrate edge-exposed in the edge exposure chamber and loading the substrate into the interface first buffer, and for transferring the substrate loaded into the interface first buffer to the exposure device; and a second interface robot disposed opposite the first interface robot with the edge exposure chamber interposed therebetween, and provided for loading substrate exposed by the exposure device to the interface second buffer, and the second interface robot is provided in a position opposite to a direction in which the outlet of the edge exposure housing is formed, and
the interface module further includes a defect inspection unit that is installed around the inlet of the edge exposure chamber, and inspects a defect of the substrate loaded into the edge exposure chamber.
